(19) United States
(12) Patent Application Publication
(10) Pub. No.: US 2024/0043281 A1
(43) Pub. Date: Feb. 8, 2024

(54) TITANIUM ZIRCONIUM OXIDE NANOPARTICLES, PHOTORESIST AND PATTERNING METHOD THEREFOR, AND METHOD FOR GENERATING PRINTED CIRCUIT BOARD

(71) Applicants: TSINGHUA UNIVERSITY, Beijing (CN); BEIJING VFORTUNE NEW ENERGY POWER TECHNOLOGY DEVELOPMENT CO., LTD., Beijing (CN)

(72) Inventors: HONG XU, Beijing (CN); XIANG-MING HE, Beijing (CN); XIAO-LIN WANG, Beijing (CN)

(21) Appl. No.: 18/266,249

(22) PCT Filed: Dec. 7, 2021
(86) PCT No.: PCT/CN2021/136049

§ 371 Date: Jun. 8, 2023

(30) Foreign Application Priority Data
Dec. 9, 2021 (CN) 202011428100.6

(51) Int. Cl. C01G 25/02; G03F 7/004; G03F 7/32; G03F 7/028; G03F 7/20

(52) U.S. Cl. CPC C01G 25/02; G03F 7/0042; G03F 7/0048; G03F 7/0045; G03F 7/32; G03F 7/028; G03F 7/2004

(57) ABSTRACT

A photoresist, a photoresist composition, a method for patterning a photoresist and a method for preparing a printed circuit board are disclosed in the present application. The photoresist includes an organic solvent and titanium zirconium oxide nanoparticles. The general molecular formula of the titanium zirconium oxide nanoparticles is TiₓZr_{y}O_{z}Lₙ, wherein x, y and z are each independently an integer in a range from 1 to 6, n is an integer in a range from 5 to 30, and L is an organic ligand including a free-radical polymerizable group.

### CROSS-REFERENCE TO RELATED APPLICATIONS

This application is an U.S. national phase application under 35 U.S.C. § 371 based upon international patent application No. PCT/CN2021/136049, filed on Dec. 7, 2021, which itself claims priority to Chinese patent application No. 202011428100.6, entitled “PHOTORESIST AND PATTERNING METHOD THEREFOR, AND METHOD FOR GENERATING PRINTED CIRCUIT BOARD”. The contents of the above identified applications are hereby incorporated herein in their entireties by reference.

### TECHNICAL FIELD

The present application relates to the technical field of photoresists, and particularly to a photoresist, a method for patterning a photoresist, and a method for preparing a printed circuit board.

### BACKGROUND

With the continuous improvement in the integration degree of large-scale integrated circuits, the feature sizes are becoming smaller, and the processing dimensions have entered the nanometer range. The development of integrated circuits needs the support of photolithography technology, and photoresists, also known as photosensitive etching resists, are the most critical basic material in photolithography. A photoresist is a composition that is sensitive to light or radiation, usually composed of a photoresist main material, a photosensitizer, a solvent, and some other additives. The photoresist main materials typically are film-forming resins, molecular glass compounds, inorganic oxides, etc. When a photoresist is exposed to or irradiated by ultraviolet light, electron beams, ion beams, excimer laser beams, X-rays, or other exposure sources, its solubility, adhesion, and other properties can be obviously changed, and thus the photoresist can form a photolithographic pattern through development in an appropriate solvent.

### SUMMARY

In view of the above, there is a need to provide a titanium zirconium oxide nanoparticle, a photoresist, a method for patterning a photoresist, and a method for preparing a printed circuit board.

A titanium zirconium oxide nanoparticle has a general molecular formula of TiₓZr_{y}O_{z}Lₙ, wherein x, y and z are each independently an integer in a range from 1 to 6, n is an integer in a range from 5 to 30, and L is an organic ligand including a free-radical polymerizable group.

In an embodiment, the general molecular formula of the titanium zirconium oxide nanoparticle is Ti₂Zr₆O₆L₂₀, Ti₂Zr₄O₄L₁₆, Ti₂Zr₄O₅L₁₄, or Ti₂Zr₄O₆L₁₂.

In an embodiment, a mass percentage of the titanium zirconium oxide nanoparticle in a photoresist is in a range from 1% to 50%.

In an embodiment, the organic ligand includes a carbon-carbon double bond.

In an embodiment, the organic ligand is one or more of acrylic acid, methylacrylic acid, or 3,3-dimethylacrylic acid.

A photoresist includes an organic solvent and titanium zirconium oxide nanoparticles as described above.

In an embodiment, the photoresist further includes a photoacid generator, the photoacid generator is capable of decomposing under light to form a photoacid catalyst, and the photoacid catalyst is capable of catalyzing aggregation of the titanium zirconium oxide nanoparticles; and/or the photoresist further includes a photo-initiator, and the photo-initiator is capable of initiating aggregation of the titanium zirconium oxide nanoparticles.

In an embodiment, the organic solvent is one or more of propylene glycol monomethyl ether acetate, propylene glycol monoethyl ether, propylene glycol monoacetate, ethylene glycol monomethyl ether acetate, ethyl acetate, butyl acetate, chloroform, or dichloromethane.

A photoresist includes an organic solvent and titanium zirconium oxide nanoparticles. The titanium zirconium oxide nanoparticle has a general molecular formula of Ti₂Zr₆O₆L₂₀, Ti₂Zr₄O₄L₁₆, Ti₂Zr₄O₅L₁₄, or Ti₂Zr₄O₆L₁₂, wherein L is an organic ligand including a free-radical polymerizable group.

In an embodiment, the organic ligand is one or more of acrylic acid, methylacrylic acid, or 3,3-dimethylacrylic acid.

A photoresist composition includes the photoresist as described above and a developer.

In an embodiment, the developer is one or more of toluene, o-xylene, m-xylene, p-xylene, mesitylene, ethyl acetate, butyl acetate, 4-methyl-2-pentanol, 4-methyl-2-pentone, methyl ethyl ketone, propylene glycol monomethyl ether acetate, propylene glycol monoethyl ether, propylene glycol monoacetate, ethylene glycol monomethyl ether acetate, 2-butanone, 2-heptanone, ethanol, n-propanol, isopropanol, n-butanol, isobutanol, n-hexane, or cyclohexane.

A method for patterning a photoresist, includes following steps of:
coating the photoresist on a substrate surface, and removing the organic solvent from the photoresist, to form a preformed film on the substrate surface;
irradiating the preformed film on the substrate surface by a light source through a mask for exposure, allowing the titanium zirconium oxide nanoparticles in an exposed region of the preformed film to aggregate; and
applying a developer to the preformed film after the exposure, allowing an unexposed region of the preformed film covered by the mask to dissolve in the developer, while the exposed region of the preformed film retains on the substrate surface due to the aggregation of the titanium-zirconium oxide nanoparticles.

In an embodiment, the light source for exposure is an ultraviolet light source, a deep ultraviolet light source, or an extreme ultraviolet light source, with an exposure dose in a range from 4 mJ/cm² to 50 mJ/cm².

In an embodiment, the light source for exposure is an electron beam light source, with an exposure dose a range from 10 μC/cm² to 10 mC/cm².

In an embodiment, the substrate is a silicon substrate.

A method for preparing a printed circuit board includes following steps of:
preparing a pre-patterned substrate including a silicon substrate and a patterned photoresist layer formed on the silicon substrate by the method for patterning a photoresist as described above; and
etching the pre-patterned substrate by dry-etching or wet-etching.

In conventional photoresists, although some metal nanoparticles can aggregate under light, the metal nanoparticles which are not irradiated by light may become unstable due to contact with water in the air and thus also aggregate. Hence, the solubility difference between the exposed and unexposed regions is not significant. The inventors found that the metal oxide nanoparticles formed by compositing titanium and zirconium are more stable in the air, and would not be affected by the air humidity to aggregate. Therefore, in the present application, the titanium zirconium oxide nanoparticles in the exposed region are aggregated under light, thus reducing solubility in the developer, while the titanium zirconium oxide nanoparticles in the unexposed region will not aggregate, thus being able to dissolve in the developer and be removed. The combination of titanium and zirconium can improve the stability of the metal nanoparticles in the air, and thus improve the solubility difference between the unexposed region and the exposed region. Therefore, the resolution of the photolithographic pattern is improved and the roughness of an etched line edge is reduced. In particular, the lithographic quality is greatly improved and suitable for devices with high precision requirements.

Moreover, the titanium zirconium oxide nanoparticles in some embodiments of the present application have organic ligands capable of free radical polymerization. On the one hand, the dispersibility of the titanium zirconium oxide nanoparticles in an organic solvent can be improved. On the other hand, the organic ligands themselves can be polymerized under light, which is beneficial to improve the solubility difference between the exposed region and the unexposed region of the photoresist, and thus beneficial to improve the quality of the pattern.

### BRIEF DESCRIPTION OF THE DRAWINGS

In order to illustrate the embodiments of the present disclosure more clearly, the drawings used in the embodiments will be described briefly. Apparently, the following described drawings are merely for the embodiments of the present disclosure, and other drawings can be derived by those of ordinary skill in the art without any creative effort.

FIG. 1 shows an optical micrograph of a patterned photoresist layer in Example 1 of the present application.

FIG. 2 shows a scanning electron micrograph of the patterned photoresist layer in Example 1 of the present application.

FIG. 3 shows a scanning electron micrograph of a patterned photoresist layer in Example 2 of the present application.

FIG. 4 shows a scanning electron micrograph of a patterned photoresist layer in Comparative Example 1 of the present application.

FIG. 5 shows a scanning electron micrograph of a patterned photoresist layer in Comparative Example 2 of the present application.

FIG. 6 shows a scanning electron micrograph of a patterned photoresist layer in Example 6 of the present application.

FIG. 7 shows a scanning electron micrograph of a patterned photoresist layer in Example 7 of the present application.

### DETAILED DESCRIPTION

The present application will now be described in detail with reference to the accompanying drawings in order to facilitate the understanding of this application. The preferred embodiments are illustrated in the accompanying drawings. However, the present application can be implemented by many different forms and is not limited to the embodiments described herein. In contrast, the specific embodiments are provided herein for a more thorough understanding of the present application.

Unless otherwise indicated, all technical and scientific terms used herein have the same meaning as those normally understood by a person skilled in the art. The terms used herein in the specification of the present application are for the purpose of describing specific embodiments only and not intended to limit the present application. The term “and/or” as used herein includes any and all combinations of one or more related listed items.

The scope of the term “light” as used in the present application includes but is not limited to ultraviolet light, deep ultraviolet light, and extreme ultraviolet light, and also broadly covers electron beams, X-rays, etc.

In recent years, the precision of photolithographic patterns is continuously increasing, and the thickness of a photolithographic film is gradually decreasing, which requires a photoresist not only to have good etching property, but also to have a large difference in solubility before and after exposure. In order to enhance the etching resistance of a photoresist, photoresist materials containing different metal oxides have been developed. However, the current metal oxides are likely to react with water in the air, and thus the solubility difference between the exposed and unexposed regions is not significant, resulting in low resolution of the photolithographic pattern and high degree of roughness at a line edge. Therefore, there is a need to provide a photoresist, a method for patterning a photoresist, and a method for preparing a printed circuit board in order to solve the problems of low resolution of the photolithographic pattern and high degree of roughness at a line edge.

An embodiment of the present application provides a titanium zirconium oxide nanoparticle. The titanium zirconium oxide nanoparticle has a general molecular formula of TiₓZr_{y}O_{z}Lₙ, wherein x, y and z are each independently an integer in a range from 1 to 6, n is an integer in a range from 5 to 30, and L is an organic ligand including a free-radical polymerizable group. An embodiment of the present application further provides a photoresist including titanium zirconium oxide nanoparticles as described above and an organic solvent.

In conventional photoresists, although some metal nanoparticles can aggregate under light, the metal nanoparticles which are not irradiated by light may become unstable due to contact with water in the air and thus also aggregate. Hence, the solubility difference between the exposed and unexposed regions is not significant. The inventors found that the metal oxide nanoparticles formed by compositing titanium and zirconium are more stable in the air, and substantially would not be affected by the air humidity to aggregate. Therefore, in the present application, the titanium zirconium oxide nanoparticles in the exposed region are aggregated under light, thus reducing solubility in a developer, while the titanium zirconium oxide nanoparticles in the unexposed region will not aggregate, thus being able to dissolve in a developer and thus be removed. The combination of titanium and zirconium can improve the stability of the metal nanoparticles in the air, and thus improve the solubility difference between the unexposed region and the exposed region. Therefore, the resolution of the photolithographic pattern is improved and the roughness of an etched line edge is reduced. In particular, the lithographic quality is greatly improved and is suitable for devices with high precision requirements.

Moreover, the titanium zirconium oxide nanoparticles in some embodiments of the present application have organic ligands capable of free radical polymerization. On the one hand, the dispersibility of the titanium zirconium oxide nanoparticles in an organic solvent can be improved. On the other hand, the organic ligands themselves can be polymerized under light, which is beneficial to improve the solubility difference between the exposed region and the unexposed region of a photoresist, and thus beneficial to improve the quality of the pattern.

In the titanium zirconium oxide nanoparticle, the organic ligands can be coated on the surface of the titanium zirconium oxide nanoparticle, or can be mixed with metal ions within the titanium zirconium oxide nanoparticle.

The general molecular formula of the titanium zirconium oxide nanoparticle is TiₓZr_{y}O_{z}Lₙ, wherein x can be selected from 1, 2, 3, 4, 5, or 6; y can be selected from 1, 2, 3, 4, 5, or 6; and z can be selected from 1, 2, 3, 4, 5, or 6. x, y and z can be the same or different, and x, y, and z respectively selected from the above values can be arbitrarily combined.

In some embodiments, x is 1, and the titanium zirconium oxide nanoparticle can be represented by one of the following molecular formulas: Ti₁Zr₁O₁Lₙ, Ti₁Zr₁O₂Lₙ; Ti₁Zr₂O₁Lₙ, Ti₁Zr₂O₂Lₙ, Ti₁Zr₂O₃Lₙ; Ti₁Zr₃O₂Lₙ, Ti₁Zr₃O₃Lₙ, Ti₁Zr₃O₄Lₙ; Ti₁Zr₄O₂Lₙ, Ti₁Zr₄O₃Lₙ, Ti₁Zr₄O₄Lₙ, Ti₁Zr₄O₅Lₙ; Ti₁Zr₅O₂Lₙ, Ti₁Zr₅O₃Lₙ, Ti₁Zr₅O₄Lₙ, Ti₁Zr₅O₅Lₙ, Ti₁Zr₅O₆Lₙ; Ti₁Zr₆O₂Lₙ, Ti₁Zr₆O₃Lₙ, Ti₁Zr₆O₄Lₙ, Ti₁Zr₆O₅Lₙ, or Ti₁Zr₆O₆Lₙ.

In some embodiments, x is 2, and the titanium zirconium oxide nanoparticle can be represented by one of the following molecular formulas: Ti₂Zr₁O₁Lₙ, Ti₂Zr₁O₂Lₙ, Ti₂Zr₁O₃Lₙ; Ti₂Zr₂O₂Lₙ, Ti₂Zr₂O₃Lₙ, Ti₂Zr₂O₄Lₙ; Ti₂Zr₃O₂Lₙ, Ti₂Zr₃O₃Lₙ, Ti₂Zr₃O₄Lₙ, Ti₂Zr₃O₅Lₙ; Ti₂Zr₄O₂Lₙ, Ti₂Zr₄O₃Lₙ, Ti₂Zr₄O₄Lₙ, Ti₂Zr₄O₅Lₙ, Ti₂Zr₄O₆Lₙ; Ti₂Zr₅O₂Lₙ, Ti₂Zr₅O₃Lₙ, Ti₂Zr₅O₄Lₙ, Ti₂Zr₅O₅Lₙ, Ti₂Zr₅O₆Lₙ; Ti₂Zr₆O₂Lₙ, Ti₂Zr₆O₃Lₙ, Ti₂Zr₆O₄Lₙ, Ti₂Zr₆O₅Lₙ, or Ti₂Zr₆O₆Lₙ.

In some embodiments, x is 3, and the titanium zirconium oxide nanoparticle can be represented by one of the following molecular formulas: Ti₃Zr₁O₂Lₙ, Ti₃Zr₁O₃Lₙ, Ti₃Zr₁O₄Lₙ; Ti₃Zr₂O₂Lₙ, Ti₃Zr₂O₃Lₙ, Ti₃Zr₂O₄Lₙ, Ti₃Zr₂O₅Lₙ; Ti₃Zr₃O₃Lₙ, Ti₃Zr₃O₄Lₙ, Ti₃Zr₃O₅Lₙ, Ti₃Zr₃O₆Lₙ; Ti₃Zr₄O₄Lₙ, Ti₃Zr₄O₅Lₙ, Ti₃Zr₄O₆Lₙ; Ti₃Zr₅O₅Lₙ, Ti₃Zr₅O₆Lₙ, or Ti₃Zr₆O₆Lₙ.

In some embodiments, x is 4, and the titanium zirconium oxide nanoparticle can be represented by one of the following molecular formulas: Ti₄Zr₁O₃Lₙ, Ti₄Zr₁O₄Lₙ, Ti₄Zr₁O₅Lₙ, Ti₄Zr₁O₆Lₙ; Ti₄Zr₂O₃Lₙ, Ti₄Zr₂O₄Lₙ, Ti₄Zr₂O₅Lₙ, Ti₄Zr₂O₆Lₙ; Ti₄Zr₃O₃Lₙ, Ti₄Zr₃O₄Lₙ, Ti₄Zr₃O₅Lₙ, Ti₄Zr₃O₆Lₙ; Ti₄Zr₄O₄Lₙ, Ti₄Zr₄O₅Lₙ, Ti₄Zr₄O₆Lₙ; Ti₄Zr₅O₅Lₙ; Ti₄Zr₅O₆Lₙ, or Ti₄Zr₆O₆Lₙ.

In some embodiments, x is 5, and the titanium zirconium oxide nanoparticles can be represented by one of the following molecular formulas: Ti₅Zr₁O₃Lₙ, Ti₅Zr₁O₄Lₙ, Ti₅Zr₁O₅Lₙ, Ti₅Zr₁O₆Lₙ; Ti₅Zr₂O₄Lₙ, Ti₅Zr₂O₅Lₙ, Ti₅Zr₂O₆Lₙ; Ti₅Zr₃O₅Lₙ, Ti₅Zr₃O₆Lₙ; Ti₅Zr₄O₅Lₙ, or Ti₅Zr₄O₆Lₙ.

In some embodiments, x is 6, and the titanium zirconium oxide nanoparticles can be represented by one of the following molecular formulas: Ti₆Zr₁O₄Lₙ, Ti₆Zr₁O₅Lₙ, Ti₆Zr₁O₆Lₙ; Ti₆Zr₂O₅Lₙ, Ti₆Zr₂O₆Lₙ; Ti₆Zr₃O₅Lₙ, Ti₆Zr₃O₆Lₙ; or Ti₆Zr₄O₆Lₙ.

In the above molecular formulas, n is any integer in a range from 5 to 30. In some embodiments, n is 6, 8, 10, 12, 16, 18, 20, 22, 24, 26, or 28. In some further embodiments, n is 12, 14, 16, or 20.

In some embodiments, in the photoresist, the titanium zirconium oxide nanoparticles can be in the same chemical composition, or the photoresist can include a variety of titanium zirconium oxide nanoparticles with different proportions of Ti, Zr, O and L.

In some embodiments, the molecular formula of the titanium zirconium oxide nanoparticle can be Ti₂Zr₆O₆L₂₀, Ti₂Zr₄O₄L₁₆, Ti₂Zr₄O₅L₁₄, or Ti₂Zr₄O₆L₁₂. The photoresist can include only one type of titanium zirconium oxide nanoparticles represented by any one of the above molecular formulas, or can include a variety of titanium zirconium oxide nanoparticles respectively represented by more than one of the above molecular formulas.

In some embodiments, the mass percentage of the titanium zirconium oxide nanoparticles in the photoresist can be in a range from 1% to 50%. Specifically, the mass percentage of the titanium zirconium oxide nanoparticles in the photoresist can be 1% to 5%, 5% to 10%, 10% to 15%, 15% to 20%, 20% to 25%, 25% to 30%, 30% to 35%, 35% to 40%, 40% to 45%, or 45% to 50%.

In some embodiments, the organic ligand includes a carbon-carbon double bond. The carbon-carbon double bond can undergo free radical addition reaction under light, resulting in the polymerization among the titanium zirconium oxide nanoparticles. One titanium zirconium oxide nanoparticle can include one, two, three or more types of organic ligands. In an embodiment, one titanium zirconium oxide nanoparticle can include two types of organic ligands, and the titanium zirconium oxide nanoparticle can be represented by TiₓZr_{y}O_{z}L1ₙ₁L2ₙ₂, wherein n1 and n2 each is an integer greater than or equal to 0, and n1+n2=n. In an embodiment, one titanium zirconium oxide nanoparticle can include three types of organic ligands, and the titanium zirconium oxide nanoparticle can be represented by TiₓZr_{y}O_{z}L1ₙ₁L2ₙ₂L₃n3, wherein n1, n2 and n3 each is an integer greater than or equal to 0, and n1+n2+n3=n. L1, L2 and L3 each represents different types of organic ligands. In some embodiments, the organic ligand is one or more of acrylic acid (AA), methylacrylic acid (MAA), or 3,3-dimethylacrylic acid (DMAA).

In some embodiments, the organic ligands L are connected to the titanium zirconium oxide through coordinate covalent bonds to form the titanium zirconium oxide nanoparticle. The organic ligand L includes

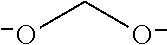

respectively connected with two adjacent Ti and/or Zr atoms in the general molecular formula of the titanium zirconium oxide nanoparticle, and the organic ligand L includes a carbon-carbon double bond. For example, L can include an alkenyl group. L is derived from an aliphatic compound or an aromatic compound. The number of carbon atoms of L can be, for example, 3 to 30, optionally 3 to 20, and further optionally 3 to 12. The number of the carbon-carbon double bonds of L can be 1 to 3, such as 1. L can include straight, branched, or alicyclic groups, and can further include 1 to 4 aromatic rings, such as a benzene ring.

In some embodiments, L can be independently selected from one of the following structures:

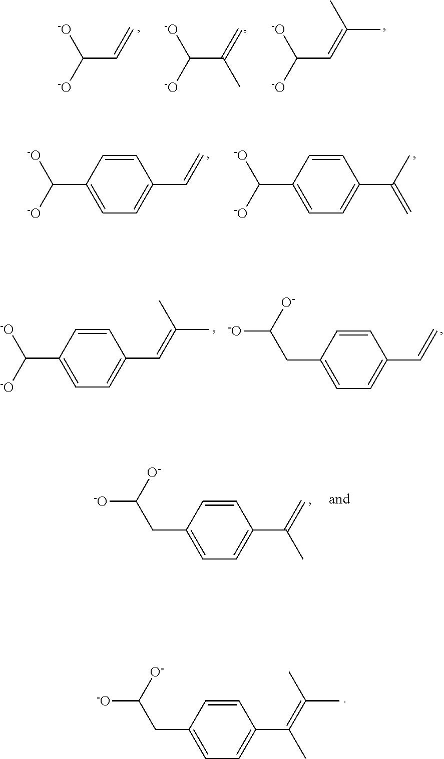

In an exemplified embodiment, L can be an acrylic acid ligand, a methylacrylic acid ligand, or a 3,3-dimethylacrylic acid ligand.

In some embodiments, the photoresist includes a photoacid generator. The photoacid generator is capable of decomposing under light to form a photoacid catalyst. The photoacid catalyst is capable of catalyzing aggregation of the titanium zirconium oxide nanoparticles. In some embodiments, the photoresist includes a photo-initiator. The photo-initiator is capable of initiating aggregation of the titanium zirconium oxide nanoparticles. In some embodiments, the mass percentage of the photoacid generator and the photo-initiator in the photoresist can be 0% to 10% and not equal to 0%, and specifically can be 0.01% to 0.1%, 0.1% to 0.5%, 0.5% to 1%, 1% to 2%, 2% to 3%, 3% to 4%, or 4% to 5%. In some embodiments, the photoacid generator can be one or more of N-hydroxynaphthalimide trifluoromethanesulfonate, N-hydroxysuccinimide trifluoromethanesulfonate, and N-(p-toluenesulfonyloxy)phthalimide. In some embodiments, the photo-initiator can be one or more of coumarins (such as 7-diethylamino-3-(2′-benzimidazolyl) coumarin, etc.), benzoins (such as benzoin dimethyl ether, etc.), or alkylphenones (such as α, α-diethoxy acetophenone, etc.) In the case of electron beam lithography or extreme ultraviolet lithography, the photoresist may not include a photoacid generator.

The organic solvent in the photoresist can be a solvent with good solubility for the titanium zirconium oxide nanoparticles, so that the titanium zirconium oxide nanoparticles can be completely dissolved and fully dispersed in the organic solvent, to avoid different polymerization degrees at different exposed regions due to the uneven dispersion of the titanium-zirconium oxide nanoparticles in the photoresist, and thus to avoid dissolution of the exposed region with the insufficient polymerization degree in a developer. In some embodiments, the organic solvent is one or more of propylene glycol monomethyl ether acetate, propylene glycol monoethyl ether, propylene glycol monoacetate, ethylene glycol monomethyl ether acetate, ethyl acetate, butyl acetate, chloroform, or dichloromethane.

In some embodiments, the titanium zirconium oxide nanoparticles can be prepared by, but not limited to, an exemplified method including following steps of:
providing a titanium ion source, a zirconium ion source, and an organic ligand source; and
mixing the titanium ion source, the zirconium ion source, and the organic ligand source in a stoichiometric ratio in a solvent, and reacting at a temperature of −25° C. to 200° C., to obtain the titanium zirconium oxide nanoparticles.

The valence of titanium ions in the titanium ion source can be +4, for example, the titanium ion source can be one or more of carboxylates, hydrated carboxylates, organic sulfonates, hydrated organic sulfonates, alkoxides, halides, nitrates, or sulfates of titanium (IV).

The valence of zirconium ions in the zirconium ion source can be +4, for example, the zirconium ion source can be one or more of carboxylates, hydrated carboxylates, organic sulfonates, hydrated organic sulfonates, alkoxides, halides, nitrates, or sulfates of zirconium (IV).

The organic ligand source is the source of the organic ligands L, which can be an aliphatic compound or an aromatic compound. The organic ligand source can include a group capable of reacting with the titanium and zirconium ion sources to form the ligand, for example include a carboxylic or anhydride group, and can also have a free-radical polymerizable group, such as an alkenyl group.

The number of carbon atoms of the organic ligand source can be, for example, 3 to 30, optionally 3 to 20, and further optionally 3 to 12. The number of alkenyl groups can be 1 to 3, and optionally 1. In some embodiments, the organic ligand source can include straight, branched, or alicyclic groups. In some embodiments, the organic ligand source can further include 1 to 4 aromatic rings, such as a benzene ring.

In some embodiments, the organic ligand source can be one or more of acrylic acid, methylacrylic acid, 3-methyl-2-butenoic acid, 4-vinyl benzoic acid, 4-(prop-1-en-2-yl) benzoic acid, 4-(2-methylprop-1-en-1-yl) benzoic acid, 2-(4-(2-methylprop-1-en-1-yl) phenyl) acetic acid, 2-(4-vinyl phenyl) acetic acid, or 2-(4-(prop-1-en-2-yl) phenyl) acetic acid.

The solvent can be one or more of water, lipids, alcohols, ethers, cycloethers, benzenes, carboxylic acids and/or alkanes, including but not limited to, one or more of tetrahydrofuran, 1,4-dioxane, benzene, toluene, p-xylene, o-xylene, m-xylene, dimethylsulfoxide, N-methylpyrrolidone, N,N-dimethylacetamide, or N,N-dimethylformamide.

The reaction temperature of the titanium ion source, the zirconium ion source, and the organic ligand source in the solvent can be in a range from 10° C. to 100° C., such as 25° C.

In an embodiment, the method further includes a step of isolating and purifying the obtained titanium zirconium oxide nanoparticles. For example, one or more steps of recrystallization, precipitation with a poor-solubility solvent such as water, extraction, washing, centrifugal separation, atmospheric distillation, reduced pressure distillation, rotary evaporation, or vacuum drying.

An embodiment of the present application further provides a photoresist composition, including the photoresist described in any one of the above embodiments and a developer. The photoresist composition can be used to form a patterned photoresist layer.

The developer matches the photoresist for dissolving the unexposed photoresist. In some embodiments, the developer is any one or more of toluene, o-xylene, m-xylene, p-xylene, mesitylene, ethyl acetate, butyl acetate, 4-methyl-2-pentanol, 4-methyl-2-pentone, methyl ethyl ketone, propylene glycol monomethyl ether acetate, propylene glycol monoethyl ether, propylene glycol monoacetate, ethylene glycol monomethyl ether acetate, 2-butanone, 2-heptanone, ethanol, n-propanol, isopropanol, n-butanol, isobutanol, n-hexane, or cyclohexane.

An embodiment of the present application further provides a method for patterning a photoresist, including following steps of:
coating the photoresist on a substrate surface, and removing the organic solvent from the photoresist, to form a preformed film on the substrate surface;
irradiating the preformed film on the substrate surface by a light source through a mask for exposure, allowing the titanium zirconium oxide nanoparticles in an exposed region of the preformed film to aggregate; and
applying a developer to the preformed film after the exposure, allowing an unexposed region of the preformed film covered by the mask to dissolve in the developer, while the exposed region of the preformed film retains on the substrate surface due to the aggregation of the titanium zirconium oxide nanoparticles.

The light source for exposure can be an ultraviolet light source, a deep ultraviolet light source, an extreme ultraviolet light source, or an electron beam light source. The extreme ultraviolet light source refers to a light source with a wavelength in a range from 10 nm to 14 nm. The ultraviolet light source can have a wavelength of 254 nm or 365 nm. In some embodiments, the light source for exposure can be an ultraviolet light source, a deep ultraviolet light source, or an extreme ultraviolet light source, with an exposure dose in a range from 4 mJ/cm² to 1000 mJ/cm², such as 4 mJ/cm² to 50 mJ/cm². In other embodiments, the light source for exposure is an electron beam light source, with an exposure dose in a range from 10 μC/cm² to 10 mC/cm². The exposure dose should be controlled within an appropriate range. If the exposure dose is too low, the energy is insufficient for the aggregation of the titanium zirconium oxide nanoparticles in the exposed region, which hinders the formation of a significant difference in solubility between the exposed region and the unexposed region, leading to poor development results. On the other hand, if the exposure dose is too high, it may cause the active substance that can initiate a reaction to diffuse into the unexposed region, resulting in a reaction of the photoresist in the unexposed region, thereby reducing the precision of the pattern.

In some embodiments, the developer is mainly used to dissolve the unaggregated titanium zirconium oxide nanoparticles. The titanium zirconium oxide nanoparticles in the exposed region are formed into aggregates by free radical polymerization of carbon-carbon double bonds of the organic ligands, or the titanium zirconium oxides with the organic ligands detached therefrom are formed into aggregates under free radical initiation. The aggregates in the exposed region do not dissolve in the developer, or the aggregates in the exposed region have a low solubility in the developer, and thus the exposed region can still be covered by aggregates even if partial dissolution occurs. The developer and the organic solvent in the photoresist can be the same or different. In some embodiments, the solubility of the titanium zirconium oxide nanoparticles in the developer is lower than that in the organic solvent of the photoresist, so as to avoid dissolution of the titanium zirconium oxide nanoparticles in the developer after the exposure due to insufficient polymerization, and thus avoid dissolution or partial dissolution of the exposed region to reduce the precision of the exposed pattern. In some embodiments, the developer can be one or more of toluene, o-xylene, m-xylene, p-xylene, ethyl acetate, butyl acetate, ethanol, n-propanol, isopropanol, n-butanol, n-hexane, or cyclohexane. In some embodiments, the developing temperature can be room temperature, such as 20° C. to 30° C.

In some embodiments, the thickness of the preformed film after removing the organic solvent can be ranged from 10 nm to 500 nm. Specifically, the thickness of the preformed film can be ranged from 10 nm to 50 nm, from 50 nm to 100 nm, from 100 nm to 150 nm, from 150 nm to 200 nm, from 200 nm to 250 nm, from 250 nm to 300 nm, from 300 nm to 350 nm, from 350 nm to 400 nm, from 400 nm to 450 nm, or from 450 nm to 500 nm.

In some embodiments, the substrate is a silicon substrate, which can be used for preparing an integrated circuit board. Other substrates that are insoluble in the developer can also be selected as required.

In some embodiments, corresponding to the deep ultraviolet or the longer wavelength light source, the mask can be a transmission mask; corresponding to an ultraviolet light source, a reflection mask can be used; and an electron beam light source can proceed with the exposure according to a pattern set by software.

An embodiment of the present application further provides a method for preparing a printed circuit board, including following steps of:
preparing a pre-patterned substrate including a silicon substrate and a patterned photoresist layer formed on the silicon substrate by the method for patterning a photoresist as described above; and
etching the pre-patterned substrate by dry-etching or wet-etching, so that the region of the silicon substrate with the photoresist layer is not etched, and the region of the silicon substrate without the photoresist layer is etched.

The patterned photoresist layer is prepared by following steps in each of Examples 1 to 5 and Comparative Examples 1 to 2, and unwanted light exposure is avoided before the development step is completed.

1. Appropriate amounts of titania zirconium oxide nanoparticles TiₓZr_{y}O_{z}Lₙ, a photoacid generator, and an organic solvent are weighed, dissolved by vibration, and then filtered to obtain a photoresist solution for later use.

2. By using a spin coater with the rotating speed and time set according to the thickness of the film to be formed, a small amount of the photoresist solution is spin-coated on a surface of a silicon wafer, and the solvent is removed therefrom to obtain a preformed film.

3. The preformed film is exposed under a light source, and the exposure dose is decided by light intensity and exposure time, i.e., the exposure dose=light intensity×exposure time. When the light source for exposure is an ultraviolet light source, a deep ultraviolet light source, or an extreme ultraviolet light source, the exposure dose can be in a range from 4 mJ/cm² to 1000 mJ/cm²; and when the light source for exposure is an electron-beam light source, the exposure dose can be in a range from 10 μC/cm² to 10 mC/cm². The exposure is performed through a mask with a preset pattern.

4. After the exposure, the silicon wafer is withdrawal to develop at room temperature using a developer. The developer can be one or more of toluene, o-xylene, m-xylene, p-xylene, ethyl acetate, butyl acetate, ethanol, n-propanol, isopropanol, n-butanol, n-hexane, or cyclohexane. Such a strong solubility and polarity conversion allows the unexposed region to dissolve while the exposed region to retain after the development. Therefore, the mask pattern is successfully transferred to the surface of the silicon wafer.

5. After the development, the silicon wafer is dried with a nitrogen gun for later use.

6. The photolithographic pattern on the silicon wafer is observed under an optical microscope or a scanning electron microscope.

### Example 1

Synthesis of Crystal Ti₂Zr₄O₄(OMc)₁₆:

1.901 g of tetrabutyl titanate, 2.681 g of zirconium n-butoxide (80% in n-butanol), and 4.095 g of methacrylic acid are mixed, stored and sealed at room temperature for a period of time to obtain crystal Ti₄Zr₄O₆(OBu)₄(OMc)₁₆. 0.5 g of Ti₄Zr₄O₆(OBu)₄(OMc)₁₆ is dissolved in dichloromethane, then 0.088 g of acetylacetone is added, stirred for 30 min to remove volatile matters, and a mixture of Ti₂Zr₄O₄(OMc)₁₆ and Ti(OBu)₂(acac)₂ as a crude product is obtained. The crude product is dissolved in dichloromethane and separated and crystallized to obtain Ti₂Zr₄O₄(OMc)₁₆, wherein Mc refers to methacrylate.

Preparation of a Patterned Photoresist Layer:

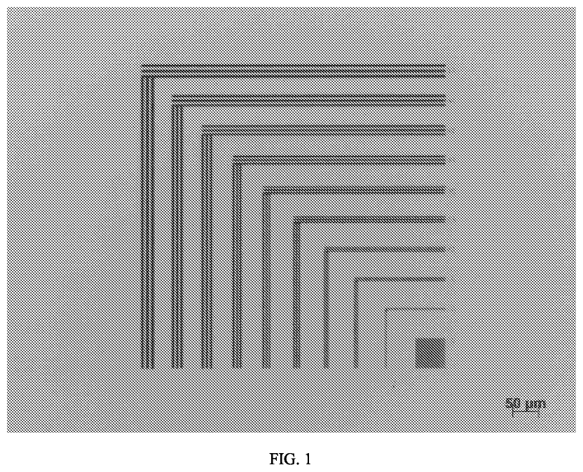

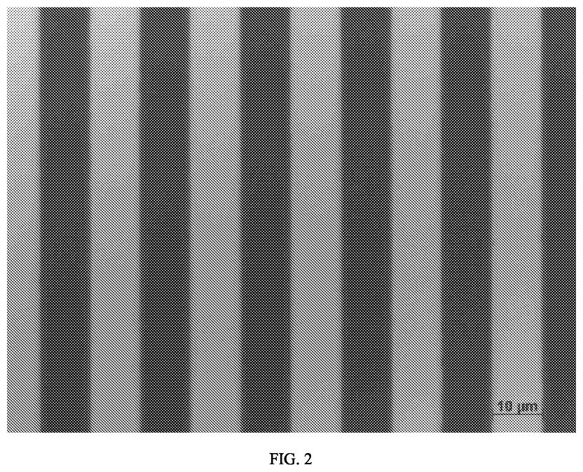

0.5 g of metal oxide nanoparticles Ti₂Zr₄O₄(OMc)₁₆ and 0.05 g of N-hydroxynaphthalimide trifluoromethanesulfonate as the photoacid generator are dissolved in 9.45 g of propylene glycol monomethyl ether acetate as the solvent, and filtered through a filter with a pore size of 0.22 μm. An appropriate amount of the filtered photoresist is dropped on a surface of a silicon wafer, homogenized at a rotating speed of 2000 r/min for 1 minute, and dried to remove the solvent at 100° C. for 1 minute. The silicon wafer is exposed under a low-pressure mercury lamp at a wavelength of 254 nm and an exposure dosage of 50 mJ/cm², and developed with toluene. The surface of the silicon wafer is dried with nitrogen gas, and then the photolithographic pattern thereon is observed under an optical microscope and a scanning electron microscope respectively, as shown in FIG. 1 and FIG. 2.

### Example 2

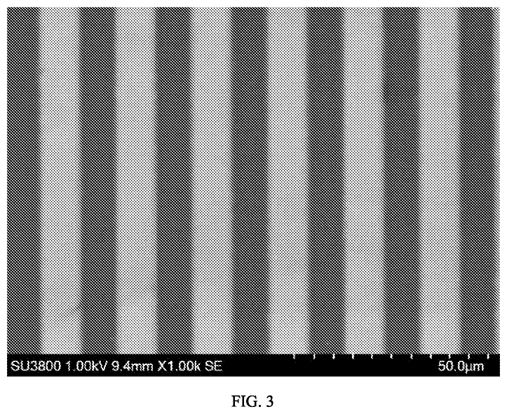

Ti₂Zr₄O₄(OMc)₁₆ is synthesized using the same method as that in Example 1, except that the crude product is not purified. Therefore, 0.5 g of the mixture of metal oxide nanoparticles Ti₂Zr₄O₄(OMc)₁₆ and Ti(OBu)₂(acac)₂, and 0.05 g of N-hydroxynaphthalimide trifluoromethanesulfonate as the photoacid generator are dissolved in 9.45 g of propylene glycol monomethyl ether acetate as the solvent, and filtered through a filter with a pore size of 0.22 μm. An appropriate amount of the filtered photoresist is dropped on a surface of a silicon wafer, homogenized at a rotating speed of 2000 r/min for 1 minute, and dried to remove the solvent at 100° C. for 1 minute. The silicon wafer is exposed under a low-pressure mercury lamp at a wavelength of 254 nm and an exposure dosage of 20 mJ/cm², and developed with toluene. The surface of the silicon wafer is dried with nitrogen gas, and then the photolithographic pattern thereon is observed under a scanning electron microscope, as shown in FIG. 3.

### Example 3

This example is substantially the same as that in Example 1, except the composition of the photoresist, which includes 5 g of titanium zirconium oxide nanoparticles Ti₃Zr₅O₅(DMAA)₂₂, 0.05 g of N-hydroxynaphthalimide trifluoromethanesulfonate as the photoacid generator, and 4.45 g of dichloromethane as the solvent, and the developer is a mixture of toluene, o-xylene and m-xylene.

### Example 4

This example is substantially the same as that in Example 1, except the composition of the photoresist, which includes 1 g of titanium zirconium oxide nanoparticles Ti₄Zr₃O₄(AA)₁₀(MAA)₁₀, 0.1 g of N-(p-toluenesulfonyloxy)phthalimide as the photoacid generator, and 8.9 g of chloroform as the solvent, and the developer is p-xylene.

### Example 5

This example is substantially the same as that in Example 1, except the composition of the photoresist, which includes 2.5 g of titanium zirconium oxide nanoparticles Ti₂Zr₆O₆(AA)₁₀(DMAA)₁₀, 0.08 g of N-hydroxynaphthalimide trifluoromethanesulfonate as the photoacid generator, and 7.42 g of dichloromethane as the solvent, and the developer is p-xylene.

### Example 6

Ti₂Zr₄O₄(OMc)₁₆ crystal is synthesized by using the same method as that in Example 1.

Preparation of a Patterned Photoresist Layer by Electron Beam Lithography:

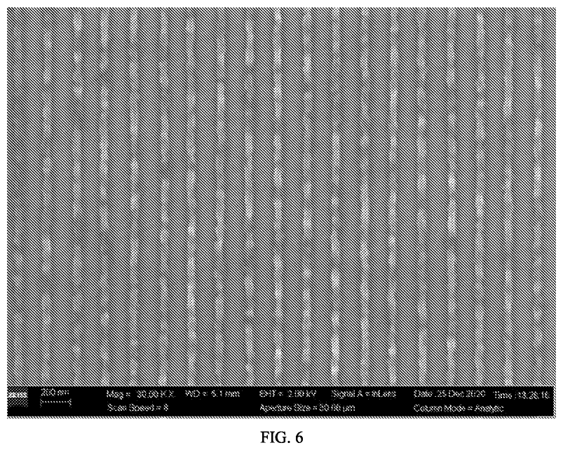

0.5 g of metal oxide nanoparticles Ti₂Zr₄O₄(OMc)₁₆ and 0.05 g of N-hydroxynaphthalimide trifluoromethanesulfonate as the photoacid generator are dissolved in 9.45 g of propylene glycol monomethyl ether acetate as the solvent, and filtered through a filter with a pore size of 0.22 μm. An appropriate amount of the filtered photoresist is dropped on a surface of a silicon wafer, homogenized at a rotating speed of 2000 r/min for 1 minute, and dried to remove the solvent at 80° C. for 1 minute. The silicon wafer is exposed in an electron beam lithography system with an exposure dosage of 1.8 mC/cm², and developed with propylene glycol monomethyl ether acetate. The surface of the silicon wafer is dried with nitrogen gas, and then the photolithographic pattern thereon is observed under a scanning electron microscope, as shown in FIG. 6.

### Example 7

Ti₂Zr₄O₄(OMc)₁₆ crystal is synthesized by using the same method as that in Example 1.

Preparation of a Patterned Photoresist Layer by Extreme Ultraviolet Lithography:

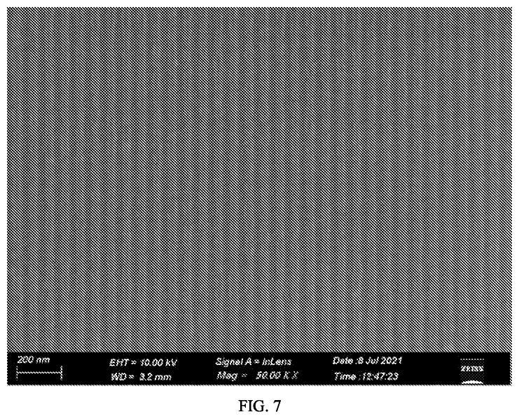

0.5 g of metal oxide nanoparticles Ti₂Zr₄O₄(OMc)₁₆ and 0.05 g of N-hydroxynaphthalimide trifluoromethanesulfonate as the photoacid generator are dissolved in 9.45 g of propylene glycol monomethyl ether acetate as the solvent, and filtered through a filter with a pore size of 0.22 μm. An appropriate amount of the filtered photoresist is dropped on a surface of a silicon wafer, homogenized at a rotating speed of 2000 r/min for 1 minute, and dried to remove the solvent at 80° C. for 1 minute. The silicon wafer is etched by extreme ultraviolet interference lithography with an exposure dosage of 77 mJ/cm², and developed with propylene glycol monomethyl ether acetate. The surface of the silicon wafer is dried with nitrogen gas, and then the photolithographic pattern thereon is observed under a scanning electron microscope, as shown in FIG. 7.

### Comparative Example 1

1 g of isopropyl titanate is mixed with 2.37 g of methacrylic acid and stirred for 5 minutes, then 2 mL of n-propanol is added and stirred for 10 minutes, then 1.23 g of water and 2 mL of n-propanol are added and stirred for 30 minutes, and the solvent is removed to obtain Ti containing nanoparticles, TiOC.

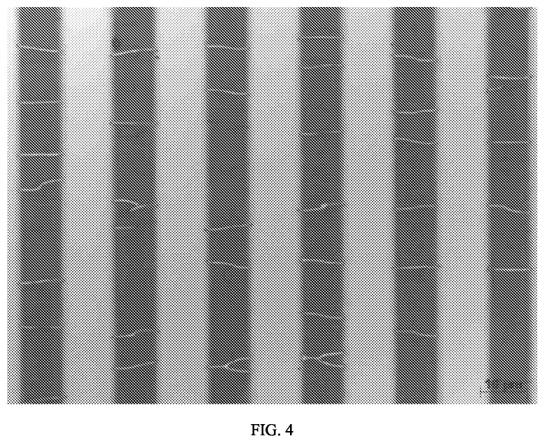

0.5 g of metal oxide nanoparticles TiOC and 0.05 g of N-hydroxynaphthalimide trifluoromethanesulfonate as the photoacid generator are dissolved in 9.45 g of propylene glycol monomethyl ether acetate as the solvent, and filtered through a filter with a pore size of 0.22 μm. An appropriate amount of the filtered photoresist is dropped on a surface of a silicon wafer, homogenized at a rotating speed of 2000 r/min for 1 minute, and dried to remove the solvent at 100° C. for 1 minute. The silicon wafer is exposed under a low-pressure mercury lamp at a wavelength of 254 nm and an exposure dosage of 50 mJ/cm², and developed with toluene. The surface of the silicon wafer is dried with nitrogen gas, and then the photolithographic pattern thereon is observed under a scanning electron microscope, as shown in FIG. 4.

### Comparative Example 2

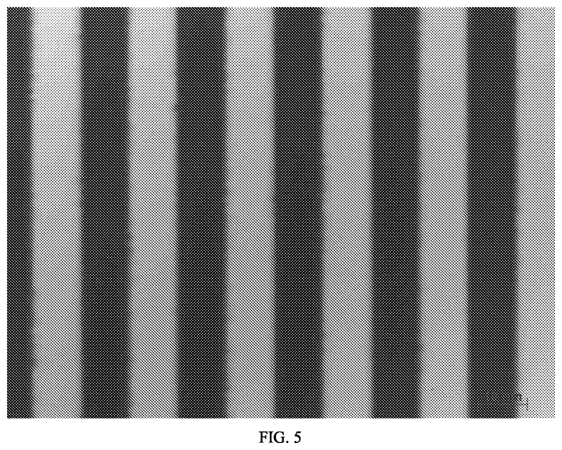

This comparative example is substantially the same as that in Comparative Example 1, except that the exposure dosage is 120 mJ/cm². The photolithographic pattern on the surface of the silicon wafer is observed under a scanning electron microscope, as shown in FIG. 5.

As shown in FIGS. 1 to 2 and 6 to 7, line shaped patterns can be obtained from the photoresist including the crystal Ti₂Zr₄O₄(OMc)₁₆ in Example 1 by respectively exposing the photoresist to a mercury lamp at 254 nm, an electron-beam light source, or an extreme ultraviolet light source, at appropriate exposure doses. The line shaped patterns have high contrast, low degree of edge roughness, and low degree of width roughness. In particular, the line shaped patterns with a line width of tens of nanometers can be obtained by electron beam lithography and extreme ultraviolet lithography. As shown in FIG. 3, a line shaped pattern at a relatively good resolution can also be obtained from the photoresist including the mixture of Ti₂Zr₄O₄(OMc)₁₂ and Ti(OBu)₂(acac)₂ in Example 2, and the photoresist has a higher sensitivity. As can be seen from FIGS. 4 and 5, a line pattern (as shown in FIG. 4) with poor contrast is obtained by exposing the photoresist including nanoparticles TiOC in the comparative example to ultraviolet light source. Due to the swelling of the patterned film, deformation occurs in the lines (white wires on the lines). By increasing the exposure dose, the swelling phenomenon can be reduced, but the edges of the lines are relatively rough (as shown in FIG. 5).

The technical features of the above-mentioned embodiments can be combined arbitrarily. In order to make the description concise, not all possible combinations of the technical features are described in the embodiments. However, as long as there is no contradiction in the combination of these technical features, the combinations should be considered as in the scope of the present disclosure.

The above-described embodiments are only several implementations of the present disclosure, and the descriptions are relatively specific and detailed, but they should not be construed as limiting the scope of the present disclosure. It should be understood by those of ordinary skill in the art that various modifications and improvements can be made without departing from the concept of the present disclosure, and all fall within the protection scope of the present disclosure. Therefore, the patent protection of the present disclosure shall be defined by the appended claims.

1. A titanium zirconium oxide nanoparticle, represented by a general molecular formula of TiₓZr_{y}O_{z}Lₙ, wherein x, y and z are each independently an integer in a range from 1 to 6, n is an integer in a range from 5 to 30, and L is an organic ligand comprising a free-radical polymerizable group.

2. The titanium zirconium oxide nanoparticle according to claim 1, wherein the general molecular formula of the titanium zirconium oxide nanoparticle is Ti₂Zr₆O₆L₂₀, Ti₂Zr₄O₄L₁₆, Ti₂Zr₄O₅L₁₄, or Ti₂Zr₄O₆L₁₂.

3. The titanium zirconium oxide nanoparticle according to claim 1, wherein a mass percentage of the titanium zirconium oxide nanoparticle in a photoresist is in a range from 1% to 50%.

4. The titanium zirconium oxide nanoparticle according to claim 1, wherein the organic ligand comprises a carbon-carbon double bond.

5. The titanium zirconium oxide nanoparticle according to claim 1, wherein the organic ligand is one or more of acrylic acid, methylacrylic acid, or 3,3-dimethylacrylic acid.

6. A photoresist, comprising titanium zirconium oxide nanoparticles according to claim 1, and an organic solvent.

7. The photoresist according to claim 6, further comprising a photoacid generator, wherein the photoacid generator is capable of decomposing under light to form a photoacid catalyst, and the photoacid catalyst is capable of catalyzing aggregation of the titanium zirconium oxide nanoparticles.

8. The photoresist according to claim 6, further comprising a photo-initiator, wherein the photo-initiator is capable of initiating aggregation of the titanium zirconium oxide nanoparticles.

9. The photoresist according to claim 6, wherein the organic solvent is one or more of propylene glycol monomethyl ether acetate, propylene glycol monoethyl ether, propylene glycol monoacetate, ethylene glycol monomethyl ether acetate, ethyl acetate, butyl acetate, chloroform, or dichloromethane.

10. A photoresist, comprising an organic solvent and titanium zirconium oxide nanoparticles, wherein a general molecular formula of the titanium zirconium oxide nanoparticles is Ti₂Zr₆O₆L₂₀, Ti₂Zr₄O₄L₁₆, Ti₂Zr₄O₅L₁₄, or Ti₂Zr₄O₆L₁₂, wherein L is an organic ligand comprising a free-radical polymerizable group.

11. The photoresist according to claim 10, wherein the organic ligand is one or more of acrylic acid, methylacrylic acid, or 3,3-dimethylacrylic acid.

12. A photoresist composition, comprising the photoresist according to claim 6 and a developer.

13. The photoresist composition according to claim 12, wherein the developer is one or more of toluene, o-xylene, m-xylene, p-xylene, mesitylene, ethyl acetate, butyl acetate, 4-methyl-2-pentanol, 4-methyl-2-pentone, methyl ethyl ketone, propylene glycol monomethyl ether acetate, propylene glycol monoethyl ether, propylene glycol monoacetate, ethylene glycol monomethyl ether acetate, 2-butanone, 2-heptanone, ethanol, n-propanol, isopropanol, n-butanol, isobutanol, n-hexane, or cyclohexane.

14. A method for patterning a photoresist, comprising following steps of:
coating the photoresist according to claim 6 on a substrate surface, and removing the organic solvent from the photoresist, to form a preformed film on the substrate surface;
irradiating the preformed film on the substrate surface by a light source through a mask for exposure, allowing the titanium zirconium oxide nanoparticles in an exposed region of the preformed film to aggregate; and
applying a developer to the preformed film after the exposure, allowing an unexposed region of the preformed film covered by the mask to dissolve in the developer, while the exposed region of the preformed film retains on the substrate surface due to the aggregation of the titanium zirconium oxide nanoparticles.

15. The method according to claim 14, wherein the light source for exposure is an ultraviolet light source, a deep ultraviolet light source, or an extreme ultraviolet light source, with an exposure dose in a range from 4 mJ/cm² to 1000 mJ/cm².

16. The method according to claim 14, wherein the light source for exposure is an electron beam light source, with an exposure dose a range from 10 μC/cm² to 10 mC/cm².

17. The method according to claim 14, wherein the substrate is a silicon substrate.

18. A method for preparing a printed circuit board, comprising following steps of:
preparing a pre-patterned substrate including a silicon substrate and a patterned photoresist layer formed on the silicon substrate by the method according to claim 14; and
etching the pre-patterned substrate by dry-etching or wet-etching.
